(19) United States
(12) Patent Application Publication
(10) Pub. No.: US 2026/0007041 A1
(43) Pub. Date: Jan. 1, 2026

(54) DISPLAY PANEL AND MANUFACTURING METHOD THEREFOR, AND DISPLAY APPARATUS

(71) Applicants: BEIJING BOE TECHNOLOGY DEVELOPMENT CO., LTD., Beijing (CN); BOE TECHNOLOGY GROUP CO., LTD., Beijing (CN)

(72) Inventors: Hejin Wang, Beijing (CN); Dawei Wang, Beijing (CN); Zheng Liu, Beijing (CN); Shiming Shi, Beijing (CN)

(73) Assignees: BEIJING BOE TECHNOLOGY DEVELOPMENT CO., LTD., Beijing (CN); BOE TECHNOLOGY GROUP CO., LTD., Beijing (CN)

(21) Appl. No.: 18/992,823

(22) PCT Filed: May 30, 2024
(86) PCT No.: PCT/CN2024/096477

§ 371 Date: Jan. 9, 2025

(30) Foreign Application Priority Data
Jun. 15, 2023 (CN) 202310716024.6

(51) Int. Cl. H10K 59/80; H10K 59/12; H10K 59/124

(52) U.S. Cl. CPC H10K 59/872; H10K 59/1201; H10K 59/124

(57) ABSTRACT

A display panel and a manufacturing method therefor, and a display apparatus. The display panel is formed by splicing a plurality of display sub-panels; and each of the plurality of display sub-panels is provided with a first display surface, the display sub-panel is provided with a first frame and a second frame, the first frame and the second frame are bent to a side away from the first display surface, and the first frame of at least one of the plurality of display sub-panels is arranged to be in contact with the second frame of a display sub-panel adjacent to the display sub-panel.

### CROSS-REFERENCE TO RELATED APPLICATIONS

The present disclosure claims the priority of the Chinese Patent Application No. 202310716024.6 filed to the China National Intellectual Property Administration on Jun. 15, 2023 and entitled “DISPLAY PANEL AND MANUFACTURING METHOD THEREFOR, AND DISPLAY APPARATUS”, the entire contents thereof are hereby incorporated by reference.

### TECHNICAL FIELD

The present disclosure relates to the technical field of display, in particular to a display panel and a manufacturing method therefor, and a display apparatus.

### BACKGROUND

A display apparatus formed by splicing a plurality of display screens usually has obvious splicing seams which affect the experience effect of a user.

### SUMMARY

In one aspect of the present disclosure, the present disclosure provides a display panel. According to some embodiments of the present disclosure, the display panel is formed by splicing a plurality of display sub-panels; and each of the plurality of display sub-panels is provided with a first display surface, the display sub-panel is provided with a first frame and a second frame, the first frame and the second frame are bent to a side away from the first display surface, and the first frame of at least one of the plurality of display sub-panels is arranged to be in contact with the second frame of a display sub-panel adjacent to the display sub-panel.

According to embodiments of the present disclosure, the display sub-panels are provided with a plurality of hollow areas.

According to embodiments of the present disclosure, the display sub-panels include a plurality of pixel island areas and a plurality of connecting bridge areas, the hollow areas are located between the pixel island areas and the connecting bridge areas, two of the adjacent pixel island areas are connected by the connecting bridge areas, and the connecting bridge areas include traces.

According to embodiments of the present disclosure, the display sub-panel includes a substrate, a first flat layer, and a first passivation layer, the substrate and the first flat layer are located in the pixel island area and the connecting bridge area, and the first passivation layer is located in the pixel island area; the first flat layer is located on one side of the substrate and is provided with a groove, a cross section of the groove in a first direction is of an inverted trapezoid, and the first direction is a direction that the substrate points to the first flat layer; and the first passivation layer covers a partial surface, away from the substrate, of the first flat layer, the first passivation layer is provided with a first opening, and an orthographic projection of the first opening on the substrate falls within a range of an orthographic projection of an edge, away from the substrate, of the groove on the substrate.

According to embodiments of the present disclosure, the display sub-panel further includes a second passivation layer, the second passivation layer is located in the pixel island area, the second passivation layer covers a surface, away from the substrate, of the first passivation layer, the bottom of the groove and at least part side wall of the groove, the second passivation layer is provided with a second opening, the area of an orthographic projection of a part, located on the bottom of the groove, of the second passivation layer on the substrate is greater than the area of an orthographic projection of the second opening on the substrate, and the orthographic projection of the part, located on the bottom of the groove, of the second passivation layer on the substrate covers the orthographic projection of the second opening on the substrate.

According to embodiments of the present disclosure, the display sub-panel further includes a pixel defining layer, an anode, a light emitting layer, and a cathode, the pixel defining layer, the anode and the cathode are located in the pixel island area, the pixel island area includes at least one pixel, the anode covers a partial surface, away from the substrate, of the second passivation layer, a plurality of third openings are defined by the pixel defining layer, the pixel defining layer covers a partial surface, away from the substrate, of the anode, at least partial area of the third openings is filled with the light emitting layer, the cathode is located on a side, away from the substrate, of the light emitting layer, the cathode covers a partial surface, away from the substrate, of the pixel defining layer, and an orthographic projection of the cathode on the substrate does not overlap with an orthographic projection of the groove on the substrate.

According to embodiments of the present disclosure, the display sub-panel is provided with a first bent part, the first bent part includes a flexible circuit board and an integrated circuit, and the first bent part is bent to the side away from the first display surface.

According to embodiments of the present disclosure, the first bent part includes a stretchable transition area located between the first display surface and the flexible circuit board and provided with a first side and a second side, the first side partially overlaps with an edge of the first display surface, and the second side at least partially overlaps with an edge of the flexible circuit board.

According to embodiments of the present disclosure, a distance between the first side and the second side is greater than or equal to one millimeter.

According to embodiments of the present disclosure, the display sub-panel is fan-shaped, and the display panel is of a sphere or a part of the sphere.

According to embodiments of the present disclosure, the display panel is of the part of the sphere, and a quantity of the display sub-panels in the display panel is any value of two to ten; or the display panel is of the sphere, and a quantity of the display sub-panels in the display panel is any value of eight to twenty.

According to embodiments of the present disclosure, the at least one display sub-panel is further provided with a third frame, the third frame is located on one end of the display sub-panel, and the third frame is bent to the side away from the first display surface.

According to embodiments of the present disclosure, a display surface of the display panel is a rectangular plane or a irregular plane, and the third frame of the at least one display sub-panel is arranged to be in contact with the third frame or the first bent part of another display sub-panel; or the display panel is provided with six display surfaces, and the six display surfaces of the display panel form six surfaces of a cuboid; or the display panel is provided with four display surfaces, and the four display surfaces of the display panel are sequentially connected to form four sides of a cuboid.

In another aspect of the present disclosure, the present disclosure provides a manufacturing method for the display panel mentioned above. According to embodiments of the present disclosure, the manufacturing method for the display panel mentioned above includes: providing a plurality of original display sub-panels; bending a first frame and a second frame of each of the plurality of original display sub-panels to a side away from a display surface of the original display sub-panel to obtain a display sub-panel; and disposing the first frame of the display sub-panel to be in contact with the second frame of another display sub-panel, and splicing the plurality of display sub-panels to form the display panel.

According to embodiments of the present disclosure, the original display sub-panel is fan-shaped, a side, facing away from the display surface, of the original display sub-panel is fitted to a mold, the first frame and the second frame of the original display sub-panel are bent to a side away from the display surface of the original display sub-panel to obtain the display sub-panel, wherein the mold is of a sphere or a part of the sphere; the first frame of one of the display sub-panels is arranged to be in contact with the second frame of another display sub-panel, the operation is repeated, and the plurality of display sub-panels are spliced to form a spherical display panel or a part of the spherical display panel; or the splicing the plurality of display sub-panels to form the display panel further includes: bending a third frame of the original display sub-panel to a side away from the display surface of the original display sub-panel; or the splicing the plurality of display sub-panels to form the display panel further includes: disposing the third frame of the display sub-panel to be in contact with the third frame or the first bent part of another display sub-panel.

According to embodiments of the present disclosure, manufacturing the original display sub-panel includes: providing an original substrate, wherein the original substrate includes a first preset area, a second preset area, and a third preset area; forming an original first planarization layer on one side of the original substrate, and removing the original first planarization layer in the second preset area; and forming an original first passivation layer on a side, away from the original substrate, of the original first planarization layer, removing the original first passivation layer in the second preset area and the third preset area, etching the original first passivation layer and the original first planarization layer in the first preset area by adopting a gas to obtain a first planarization layer, and forming an opening in the original first passivation layer, wherein the first planarization layer is provided with a groove, a cross section of the groove in a first direction is of an inverted trapezoid, and the first direction is a direction that the original substrate points to the first planarization layer; and an orthographic projection of the first opening on the original substrate falls within a range of an orthographic projection of an edge, away from the original substrate, of the groove on the original substrate.

According to embodiments of the present disclosure, manufacturing the original display sub-panel further includes: forming an original second passivation layer on a side, away from the original substrate, of the original first passivation layer, wherein the original second passivation layer covers a surface, away from the original substrate, of the original first passivation layer, the bottom of the groove and at least part side wall of the groove, the original second passivation layer is provided with a second opening, the area of an orthographic projection of a part, located on the bottom of the groove, of the original second passivation layer on the original substrate is greater than the area of an orthographic projection of the second opening on the original substrate, and the orthographic projection of the part, located on the bottom of the groove, of the original second passivation layer on the original substrate covers the orthographic projection of the second opening on the original substrate; performing exposure etching on the original second passivation layer and the original first passivation layer to form a first via hole, thereby obtaining a second passivation layer and a first passivation layer; forming a plurality of light emitting units in the first preset area; and removing the original substrate in the second preset area to form the hollow area.

In a further aspect of the present disclosure, the present disclosure provides a manufacturing method for a display panel. According to embodiments of the present disclosure, the manufacturing method for the display panel includes: calculating a pixel spacing according to a width of a fourth frame, a width of a fifth frame and a fit tolerance of a display sub-panel; manufacturing a plurality of display sub-panels, wherein a spacing between two adjacent pixels in each display sub-panel is the pixel spacing, and the display sub-panel is provided with the fourth frame and the fifth frame; and splicing the plurality of display sub-panels to form the display panel, wherein the fourth frame of at least one of the plurality of display sub-panels is arranged to be in contact with the fifth frame of a display sub-panel adjacent to the display sub-panel.

In a yet further aspect of the present disclosure, the present disclosure provides a display apparatus. According to embodiments of the present disclosure, the display apparatus includes the display panel mentioned above or the display panel manufactured by using the method mentioned above. Therefore, the display apparatus has a good display effect.

The above-mentioned description is only a summary of the technical solutions of the present disclosure. In order to more clearly know about the technical means of the present disclosure, they may be implemented according to the content of the description. Moreover, in order to make the above-mentioned and other objects, features, and advantages of the present disclosure more obvious and comprehensible, specific implementations of the present disclosure will be listed below.

### BRIEF DESCRIPTION OF THE DRAWINGS

In order to describe the technical solutions in the embodiments of the present disclosure or the prior art more clearly, the accompanying drawings required for describing the embodiments or the prior art will be briefly introduced below. Apparently, the accompanying drawings in the following description show only some embodiments of the present disclosure, and persons skilled in the art may still derive other accompanying drawings from these accompanying drawings without creative efforts.

FIG. 1 shows a schematic diagram of a partial structure of a display panel according to one embodiment of the present disclosure;

FIG. 2 shows a schematic structural diagram of a display panel according to another embodiment of the present disclosure;

FIG. 3 shows a schematic structural diagram of a display panel according to a further embodiment of the present disclosure;

FIG. 4 shows a schematic structural diagram of a display panel according to a further embodiment of the present disclosure;

FIG. 5 shows a schematic structural diagram of a display panel according to a further embodiment of the present disclosure;

FIG. 6 shows a schematic structural diagram of a display panel according to a further embodiment of the present disclosure;

FIG. 7 shows a schematic structural diagram of a display panel according to a further embodiment of the present disclosure;

FIG. 8 shows a schematic structural diagram of a display panel according to a further embodiment of the present disclosure;

FIG. 9 shows a schematic structural diagram of a display panel according to a further embodiment of the present disclosure;

FIG. 10 shows a schematic structural diagram of a display sub-panel according to one embodiment of the present disclosure;

FIG. 11 shows a schematic structural diagram of a display sub-panel according to another embodiment of the present disclosure;

FIG. 12 shows a schematic structural diagram of a display sub-panel according to a further embodiment of the present disclosure;

FIG. 13 shows a schematic diagram of a partial structure of a display sub-panel according to one embodiment of the present disclosure;

FIG. 14 shows a schematic diagram of a partial structure of a display sub-panel according to another embodiment of the present disclosure;

FIG. 15 shows a schematic diagram of a partial structure of a display sub-panel according to a further embodiment of the present disclosure;

FIG. 16 shows a schematic diagram of a partial structure of a display sub-panel according to a further embodiment of the present disclosure;

FIG. 17 shows a schematic diagram of a partial structure of a display sub-panel according to a further embodiment of the present disclosure;

FIG. 18 shows a schematic diagram of a partial structure of a display panel according to one embodiment of the present disclosure;

FIG. 19 shows a schematic diagram of a partial structure of a display panel according to one embodiment of the present disclosure;

FIG. 20 shows a schematic diagram of a partial structure of a display panel according to one embodiment of the present disclosure;

FIG. 21 shows a schematic diagram of a partial structure of a display panel according to one embodiment of the present disclosure;

FIG. 22 shows a partial process diagram of a manufacturing method for a display panel according to one embodiment of the present disclosure;

FIG. 23 shows a partial process diagram of a manufacturing method for a display panel according to one embodiment of the present disclosure;

FIG. 24 shows a partial process diagram of a manufacturing method for a display panel according to one embodiment of the present disclosure;

FIG. 25 shows a schematic structural diagram of a display sub-panel according to one embodiment of the present disclosure;

FIG. 26 shows a schematic structural diagram of a display sub-panel according to another embodiment of the present disclosure;

FIG. 27 shows a schematic structural diagram of a display panel according to one embodiment of the present disclosure;

FIG. 28 shows a schematic structural diagram of a display panel according to another embodiment of the present disclosure;

FIG. 29 shows a schematic process diagram of a manufacturing method for a display panel according to one embodiment of the present disclosure; and

FIG. 30 shows a schematic process diagram of a manufacturing method for a display panel according to another embodiment of the present disclosure.

### DETAILED DESCRIPTION OF THE EMBODIMENTS

In order to make objects, technical solutions and advantages of the embodiments of the present disclosure clearer, the technical solutions in the embodiments of the present disclosure will be described clearly and completely below in conjunction with accompanying drawings in the embodiments of the present disclosure. Apparently, the described embodiments are a part of the embodiments of the present disclosure, not all the embodiments. Based on the described embodiments of the present disclosure, all other embodiments obtained by persons skilled in the art without creative efforts shall fall within the protective scope of the present disclosure.

The embodiments of the present disclosure will be described in detail below. Embodiments described below are exemplary and are only intended to explain the present disclosure, rather than to be understood as limitations on the present disclosure. Specific technologies or conditions unspecified in the embodiments will be implemented according to technologies or conditions described in documents within the art or a product specification.

An ordinary flexible display screen cannot directly form a non-planar screen with a biaxial curvature, especially a spherical display screen, which is due to a fact that the area of a flat display screen will change greatly when the flat display screen becomes the spherical display screen, and the flexible display screen adopts a high-temperature-resistant plastic substrate having no great reversible deformation so as to be difficult to directly stretch into a spherical structure. There are two main ideas to form the spherical display screen: the first idea is that a Light Emitting Diode (LED) bead driven by a chip is directly mounted on a flexible base plate which is spliced after is slightly stretched to deform, and a display screen manufactured in such a way is relatively low in resolution, huge in volume and suitable for long-distance watching in super-large occasions such as a large convention and exhibition center; and the second idea is that a stretchable display screen is used, the display screen is stretched to form a spherical curved screen, the resolution of such a display screen is superior to that of an LED display screen driven by a chip, the stretchable display screen can be prepared by forming a hole in the high-temperature-resistant plastic substrate, the resolution of the display screen will be lowered due to the existence of the hole, but the resolution will be further lowered greatly by directly fitting the stretchable display screen to the spherical surface, and if a sealed spherical screen is required to be formed, at least two hemispheres are required to be combined, and an obvious splicing seam will be formed between the two hemispheres to affect a display effect. In addition, a display apparatus with a large plane or a plurality of planes is formed by splicing planar screens, and a splicing seam is also easily formed on the display apparatus to affect a watching effect of a user.

Since the splicing seam is caused by frames and a fit tolerance of the display screen, by bending frames of the display screen to a side away from a display surface and disposing frames of two adjacent display screens to be in contact, the technical problem of the splicing seam of the display screen can be at least relieved to a certain extent and even solved. By using such a method, a plurality of display screens can be spliced into display screens with various shapes, such as a spherical screen, a cuboid display screen, and a large-sized planar screen. In addition, a pixel spacing can also be firstly calculated according to widths of frames and the fit tolerance of the display screen. When the display screen is manufactured, pixels can be manufactured according to the calculated pixel spacing, in this way, during picture display, the splicing seam is not easy to form on the display screen manufactured by directly splicing the frames of the plurality of display screens.

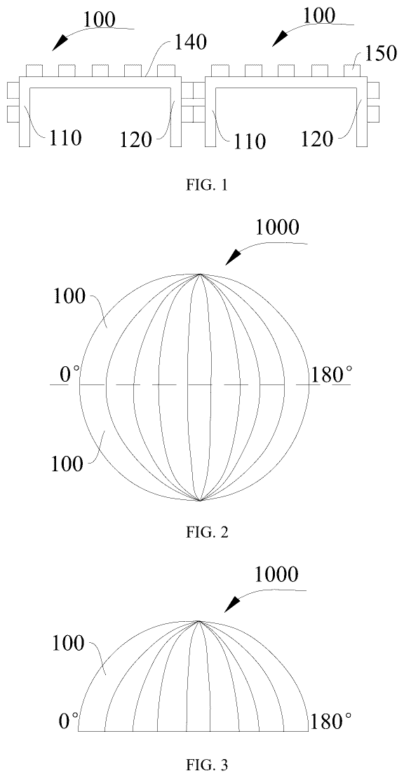

In one aspect of the present disclosure, the present disclosure provides a display panel. According to embodiments of the present disclosure, refer to FIG. 1 to FIG. 9, the display panel 1000 can be formed by splicing a plurality of display sub-panels 100, wherein each of the plurality of display sub-panels 100 is provided with a first display surface 140, the display sub-panel 100 is provided with a first frame 110 and a second frame 120, the first frame 110 and the second frame 120 are bent to a side away from the first display surface 140, and the first frame 110 of at least one of the plurality of display sub-panels 100 is arranged to be in contact with the second frame 120 of a display sub-panel 100 adjacent to the display sub-panel 100. Thus, by disposing the first frames and the second frames of the adjacent display sub-panels to be in contact, the density of pixels at a splicing position of the adjacent display sub-panels can be basically consistent with the density of pixels in a single display sub-panel, so that it is not easy for a watcher to observe the splicing seam when a picture is displayed, and the display panel has a better display effect. It should be noted that the first display surface 140 is a light emergent surface of the display sub-panel 100.

According to some embodiments of the present disclosure, refer to FIG. 1, the first frame 110 and the second frame 120 can be bent to a direction away from the first display surface 140 for ninety degrees, and the first frame 110 of one of the display sub-panels is arranged to be in contact with the second frame 120 of another display sub-panel. Thus, parts, not provided with the pixels, in the first frame and the second frame are not located in the same plane as the first display surface, and a spacing between pixels of edges of the first display surfaces of two adjacent display sub-panels is basically consistent with a pixel spacing in the single display sub-panel, so that the display panel obtained by splicing can have no obvious splicing seam, which is beneficial to improving a display effect of the display panel, and then providing a better experience effect for the watcher. It should be noted that in order to clearly describe situations of the two adjacent display sub-panels, FIG. 1 only shows two display sub-panels in a display panel; and in addition, pixels 150 in FIG. 1 are shown in a form of protrusions, which is only intended to indicate that pixel structures are arranged in corresponding areas.

It should be noted that a Gate Driver on Array (GOA) arranged on an array base plate and a non-display area can be provided in the first frame and the second frame. In addition, it should be further noted that the first frame and the second frame can also be bent to the side away from the first display surface for an angle other than ninety degrees as long as the frames of the two adjacent display sub-panels can be arranged to be in contact.

According to embodiments of the present disclosure, refer to FIG. 2 to FIG. 9, the plurality of display sub-panels can be spliced into display panels with different shapes.

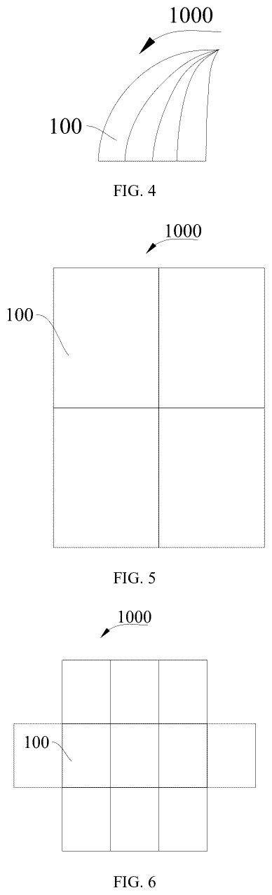

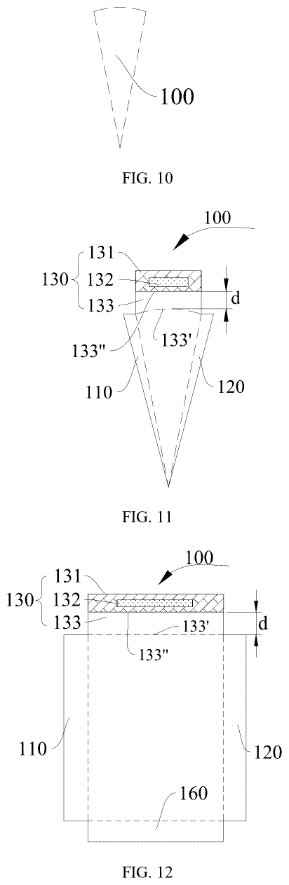

According to some embodiments of the present disclosure, refer to FIG. 2 to FIG. 4, FIG. 10 and FIG. 11, the display sub-panel 100 can be fan-shaped, and the display panel 1000 can be of a sphere or a part of the sphere. Specifically, refer to FIG. 2, the display panel can be of a sphere; refer to FIG. 3, the display panel can be of a hemisphere; and refer to FIG. 4, the display panel can be a part of the hemisphere.

According to some embodiments of the present disclosure, the display panel 1000 can be the part of the sphere, and a quantity of the display sub-panels 100 in the display panel 1000 can be any value of two to ten, for example, the display panel 1000 can be formed by splicing two, four, five, six, eight or ten display sub-panels 100. The display sub-panels with the above-mentioned quantity are spliced to form the display panel which is the part of the sphere, the stretching amount of the display sub-panel is lower, and a higher resolution can be maintained after stretching, which is beneficial to improving the display effect of the display panel.

According to some embodiments of the present disclosure, the display panel 1000 can be of the sphere, and a quantity of the display sub-panels 100 in the display panel can be any value of eight to twenty, for example, the display panel 1000 can be formed by splicing eight, ten, twelve, sixteen or twenty display sub-panels 100. The quantity of the display sub-panels is within the above-mentioned range, and the display sub-panels can be spliced within a certain actual stretching amount range to form a spherical display panel. Compared with a display panel directly stretched to be of a sphere, the spherical display panel formed by splicing the display sub-panels within the above-mentioned quantity range can maintain a higher resolution, so that the display panel has a better display effect.

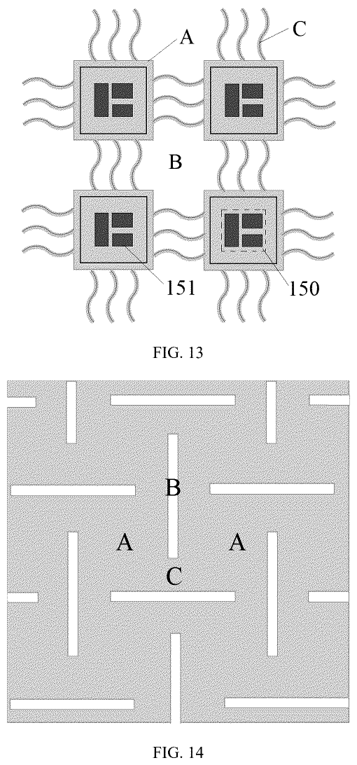

According to some embodiments of the present disclosure, refer to FIG. 1, FIG. 11 (in order to facilitate showing a structure of the display sub-panel, FIG. 11 shows a structural diagram obtained before the display sub-panel is bent, and a structural diagram obtained after the display sub-panel is bent can refer to FIG. 10) and FIG. 12, the display sub-panel 100 can also be provided with a first bent part 130, the first bent part 130 includes a flexible circuit board 131 and an integrated circuit 132, and the first bent part 130 is bent to the side away from the first display surface 140. Both of the flexible circuit board and the integrated circuit have no display function, and therefore, the flexible circuit board and the integrated circuit are arranged on the side away from the first display surface, which can increase the utilization ratio of the display panel, thereby being beneficial to improving the display effect of the display panel.

According to some other embodiments of the present disclosure, refer to FIG. 1, FIG. 11 and FIG. 12, the first bent part 130 can further include a stretchable transition area 133 located between the first display surface and the flexible circuit board 131 and provided with a first side 133′ and a second side 133″, the first side 133′ partially overlaps with an edge of the first display surface 140, and the second side 133″ at least partially overlaps with an edge of the flexible circuit board 131. The flexible circuit board and the integrated circuit have poorer stretchability, and the stretchable transition area has better stretchability, so that the stretchable transition area can be bent to achieve the purpose of bending the flexible circuit board and the integrated circuit to the side away from the first display surface.

According to some embodiments of the present disclosure, refer to FIG. 11 and FIG. 12, a distance d between the first side 133′ and the second side 133″ can be greater than or equal to one millimeter, for example, the distance between the first side 133′ and the second side 133″ can be one millimeter, one point five millimeters, two millimeters, two point five millimeters, three millimeters, etc. The distance between the first side 133′ and the second side 133″ is set to be greater than or equal to one millimeter, which can be more beneficial to the bending of the first bent part to the side away from the first display surface and can avoid damaging the flexible circuit board or the integrated circuit during bending.

According to some other embodiments of the present disclosure, refer to FIG. 1 and FIG. 12, in the display panel, at least one display sub-panel 100 is further provided with a third frame 160, the third frame 160 can be located on one end of the display sub-panel 100, and the third frame 160 is bent to the side away from the first display surface 140. According to some embodiments of the present disclosure, refer to FIG. 12, the display sub-panel 100 can be rectangular, and a display panel with a larger plane or a display panel with a plurality of display surfaces can be spliced by using the rectangular display sub-panel.

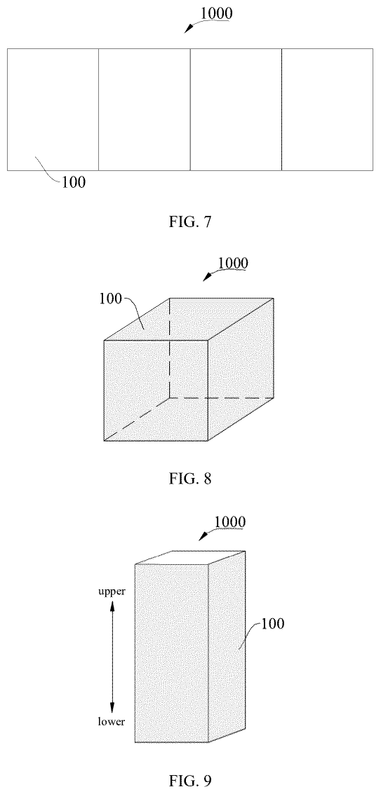

According to some embodiments of the present disclosure, refer to FIG. 5 to FIG. 7, a display panel with a rectangular plane (as shown in FIG. 5 and FIG. 7) or a display panel with a irregular plane (as shown in FIG. 6) can be formed by splicing a plurality of rectangular display sub-panels 100.

According to some embodiments of the present disclosure, refer to FIG. 5, a display surface of the display panel 1000 can be a rectangular plane, and the third frame 160 of the at least one display sub-panel 100 is arranged to be in contact with the third frame 160 or the first bent part 130 of another display sub-panel 100.

According to some other embodiments of the present disclosure, refer to FIG. 7, the display panel 1000 can be obtained by splicing a plurality of rectangular display sub-panels 100, the plurality of display sub-panels are sequentially arranged into a row, a width of the display panel 1000 is equal to a length of the display sub-panel, and a length of the display panel is equal to the sum of lengths of the plurality of display sub-panels.

According to some further embodiments of the present disclosure, refer to FIG. 6, the display surface of the display panel 1000 can be a irregular plane, and the third frame 160 of the at least one display sub-panel 100 is arranged to be in contact with the third frame 160 or the first bent part 130 of another display sub-panel 100.

According to embodiments of the present disclosure, refer to FIG. 8 and FIG. 9, a display panel with a plurality of planar display surfaces can be formed by splicing a plurality of display sub-panels.

According to some embodiments of the present disclosure, refer to FIG. 8, the display panel 1000 can be provided with six display surfaces, and the six display surfaces of the display panel form six surfaces of a cuboid, that is, the display panel can be of a cuboid structure. According to some other embodiments of the present disclosure, refer to FIG. 9, the display panel 1000 can be provided with four display surfaces, the four display surfaces of the display panel 1000 are sequentially connected to form four sides of a cuboid, and the display panel can be of a hollow structure. Optionally, the plurality of display sub-panels can also be spliced to form three-dimensional structures with other shapes, such as a triangular prism with a hollow structure, a prism with five sides, and an annular structure (an inner surface and an outer surface of the annular structure can both display pictures). It should be noted that each planar display surface of the display panel in FIG. 8 and FIG. 9 can also be formed by splicing a plurality of display sub-panels.

According to some embodiments of the present disclosure, refer to FIG. 13 and FIG. 14, the display sub-panels 100 can be provided with a plurality of hollow areas B. By disposing the plurality of hollow areas, the display sub-panels can have better stretchability and can bear deformation at a certain extent, so that it is more beneficial to forming display panels with different shapes, such as a display panel with an arc surface, by splicing; that is, the display sub-panels have greater stretchable deformation and can be stretched to form a spherical or arc surface structure.

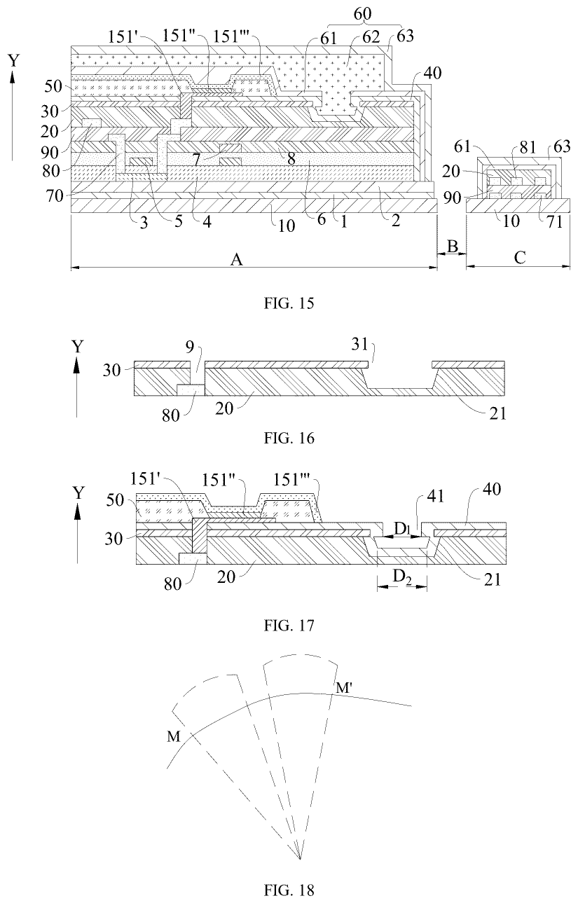

According to some embodiments of the present disclosure, refer to FIG. 13 and FIG. 14, the display sub-panels 100 can include a plurality of pixel island areas A and a plurality of connecting bridge areas C, the hollow areas B are located between the pixel island areas A and the connecting bridge areas C, two of the adjacent pixel island areas A are connected by the connecting bridge areas C, and the connecting bridge areas C can include traces (refer to FIG. 15, each of the connecting bridge areas C can include a first trace 71 and a second trace 81). Therefore, the stretchability of the display sub-panels can be further improved, then, it is beneficial to forming a display panel with an arc surface by splicing the display sub-panels and further improving the overall performance of the display panel; and the traces of the connecting bridge areas can be connected to pixel structures of the pixel island areas, thereby providing voltage signals to pixels.

According to some embodiments of the present disclosure, refer to FIG. 15 to FIG. 17, the display sub-panel 100 can include a substrate 10, a first planarization layer 20, a first passivation layer 30, a second passivation layer 40, a pixel defining layer 50, an anode 151′, a light emitting layer 151″, and a cathode 151′″, wherein the anode 151′, the light emitting layer 151″ and the cathode 151′″ form a light emitting unit. Refer to FIG. 15, the substrate 10 and the first planarization layer 20 are located in the pixel island area A and the connecting bridge area C, and the first passivation layer 30, the second passivation layer 40, the pixel defining layer 50, the anode 151′, the light emitting layer 151″ and the cathode 151′″ are located in the pixel island area A.

According to embodiments of the present disclosure, refer to FIG. 15 to FIG. 17, the first planarization layer 20 is located on one side of the substrate 10 and is provided with a groove 21, a cross section of the groove 21 in a first direction is of an inverted trapezoid, and the first direction (i.e., a Y direction shown in FIG. 15 to FIG. 17) is a direction that the substrate 10 points to the first planarization layer 20, and an orthographic projection of the bottom of the groove 21 on the substrate 10 falls within a range of an orthographic projection of an edge, away from the substrate 10, of the groove 21 on the substrate 10, that is, the size of a side, close to the substrate 10, of the groove 21 is smaller than the size of a side, away from the substrate 10, of the groove 21. The first passivation layer 30 covers a partial surface, away from the substrate 10, of the first planarization layer 20, the first passivation layer 30 is provided with a first opening 31, and an orthographic projection of the first opening 31 on the substrate 10 falls within a range of an orthographic projection of an edge, away from the substrate 10, of the groove 21 on the substrate 10, that is, the size of the first opening 31 is smaller than the size of the side, away from the substrate 10, of the groove 21. Therefore, the first planarization layer and the first passivation layer form an undercut structure at the groove, which can at least prevent a cathode material from entering the downside of a “cap peak” of the first passivation layer to a certain extent when the cathode material is deposited, thereby being beneficial to improving the overall stability of the display panel and then prolonging the service life of the display panel.

According to some embodiments of the present disclosure, refer to FIG. 15 and FIG. 17, the second passivation layer 40 covers a surface, away from the substrate 10, of the first passivation layer 30, the bottom of the groove 21 and at least part side wall of the groove 21, the second passivation layer 40 is provided with a second opening 41, the area of an orthographic projection of a part, located on the bottom of the groove 21, of the second passivation layer 40 on the substrate 10 is greater than the area of an orthographic projection of the second opening 41 on the substrate 10, and the orthographic projection of the part, located on the bottom of the groove 21, of the second passivation layer 40 on the substrate 10 covers the orthographic projection of the second opening 41 on the substrate 10. Specifically, refer to FIG. 17, the sectional size D₂ of a part, located on the bottom of the groove 21, of the second passivation layer 40 is greater than the sectional size D₁ of the second opening 41. Therefore, a structure formed at the groove by the second passivation layer and the first passivation layer can further prevent a cathode material from entering the downside of a “cap peak” of the first passivation layer when the cathode material is deposited, thereby being beneficial to improving the stability of the display panel and prolonging the service life of the display panel.

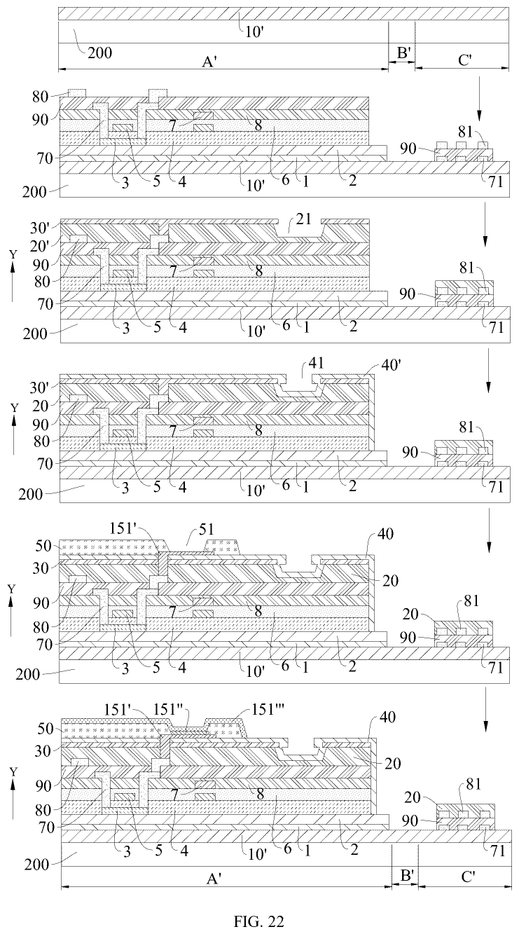

According to some embodiments of the present disclosure, the pixel island area A can include at least one pixel 150. Refer to FIG. 13, each pixel island area A includes a pixel 150, as shown in a dashed box in FIG. 13, each pixel 150 can be composed of three sub-pixels 151. Specifically, each pixel 150 can include a blue sub-pixel, a red sub-pixel, and a green sub-pixel. Refer to FIG. 15, FIG. 17 and FIG. 22, the anode 151′ covers a partial surface, away from the substrate 10, of the second passivation layer 40, a plurality of third openings 51 (FIG. 22 only shows one third opening 51) are defined by the pixel defining layer 50, the pixel defining layer 50 covers a partial surface, away from the substrate 10, of the anode 151′, at least partial area of the third openings 51 is filled with the light emitting layer 151″, the cathode 151′″ is located on a side, away from the substrate 10, of the light emitting layer 151″, the cathode 151′″ covers a partial surface, away from the substrate 10, of the pixel defining layer 50, and an orthographic projection of the cathode 151′″ on the substrate 10 does not overlap with an orthographic projection of the groove 21 on the substrate 10. Therefore, it is beneficial to further improving the overall stability of the display panel and prolonging the service life of the display panel.

According to embodiments of the present disclosure, refer to FIG. 15 and FIG. 17, the display sub-panel can further include a packaging layer 60 which can be of a thin-film packaging structure. Specifically, the packaging layer 60 can include a first inorganic packaging film layer 61, an organic packaging film layer 62, and a second inorganic packaging film layer 63, wherein the connecting bridge area C is only provided with the first inorganic packaging film layer 61 and the second inorganic packaging film layer 63. Refer to FIG. 15, in the pixel island area A, the first inorganic packaging film layer 61 covers at least partial surface, away from the substrate 10, of the cathode 151′″ and a partial surface, away from the substrate 10, of the second passivation layer 40; the organic packaging film layer 62 covers a surface, away from the substrate 10, of the first inorganic packaging film layer 61 and a partial surface, away from the substrate 10, of the second passivation layer 40, and at least partial area of the second opening 41 is filled with the organic packaging film layer 62; and the second inorganic packaging film layer 63 covers at least partial surface, away from the substrate 10, of the organic packaging film layer 62 and a partial surface, away from the substrate 10, of the first inorganic packaging film layer 61. The packaging layer can prevent external water and oxygen from invading into the light emitting layer and the cathode, thereby further improving the stability of the display panel and being beneficial to further prolonging the service life of the display panel.

According to some embodiments of the present disclosure, refer to FIG. 15, the pixel island area A of the display sub-panel can further include a barrier layer 1, a buffer layer 2, an active layer 3, a first gate insulation layer 4, a first gate layer 5, a second gate insulation layer 6, a second gate layer 7, a first source-drain electrode layer 70, an interlayer dielectric layer 8, and a second planarization layer 90. The substrate 10, the barrier layer 1 and the buffer layer 2 are sequentially stacked, and the active layer 3 covers a partial surface, away from the substrate 10, of the buffer layer 2; the first gate insulation layer 4 covers a partial surface, away from the substrate 10, of the buffer layer 2 and a partial surface, away from the substrate 10, of the active layer 3; the first gate layer 5 covers a partial surface, away from the substrate 10, of the first gate insulation layer 4, the first gate layer 5 can include a first gate and a trace structure arranged on the same layer as the first gate, and an orthographic projection of the first gate on the substrate 10 covers a partial surface of an orthographic projection of the active layer 3 on the substrate 10; the second gate insulation layer 6 covers at least partial surface, away from the substrate 10, of the first gate layer 5 and a partial surface, away from the substrate 10, of the first gate insulation layer 4; the second gate layer 7 covers a partial surface, away from the substrate 10, of the second gate insulation layer 6; the interlayer dielectric layer 8 covers the partial surface, away from the substrate 10, of the second gate insulation layer 6 and at least partial surface, away from the substrate 10, of the second gate layer 7; and the first source-drain electrode layer 70 covers a partial surface, away from the substrate 10, of the interlayer dielectric layer 8, passes through the interlayer dielectric layer 8 and the second gate insulation layer 6, and is in contact with the active layer 3. Refer to FIG. 15 to FIG. 17, the second planarization layer 90 covers at least partial surface, away from the substrate 10, of the first source-drain electrode layer 70, a second source-drain electrode layer 80 covers a partial surface, away from the substrate 10, of the second planarization layer 90, moreover and is in contact with the first source-drain electrode layer 70 via a via hole, and the anode 151′ is in contact with the second source-drain electrode layer 80 via a first via hole 9; and the first planarization layer 20 covers the partial surface, away from the substrate 10, of the second planarization layer 90 and at least partial surface, away from the substrate 10, of the second source-drain electrode layer 80.

According to some embodiments of the present disclosure, refer to FIG. 15, the connecting bridge area C includes the substrate 10, the first trace 71, the second planarization layer 90, the second trace 81, the first planarization layer 20, the first inorganic packaging film layer 61, and the second inorganic packaging film layer 63, wherein the second planarization layer 90 covers a surface, away from the substrate 10, of the first trace 71, the second trace 81 covers the partial surface, away from the substrate 10, of the second planarization layer 90, the first planarization layer 20 covers a surface, away from the substrate 10, of the second trace 81 and the partial surface, away from the substrate 10, of the second planarization layer 90, the first inorganic packaging film layer 61 covers the surface, away from the substrate 10, of the first planarization layer 20, and the second inorganic packaging film layer 63 covers the surface, away from the substrate 10, of the first inorganic packaging film layer 61. The first trace 71 can be formed by adopting the same process steps as the first source-drain electrode layer 70 in the pixel island area A, and the second trace 81 can be formed by adopting the same process steps as the second source-drain electrode layer 80 in the pixel island area A.

In general, the splicing seam of the display panel provided in the present disclosure is not obvious, and the display panel can maintain a higher resolution and has a better display effect.

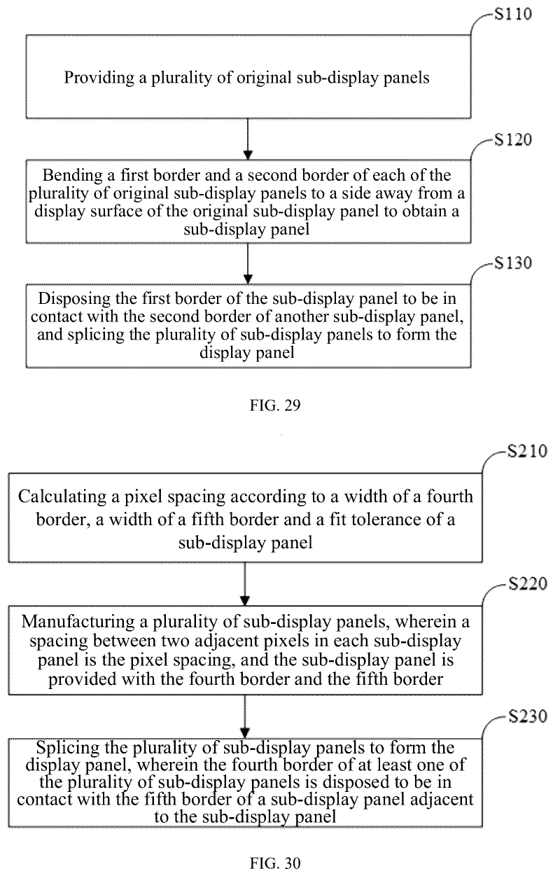

In another aspect of the present disclosure, the present disclosure provides a manufacturing method for the display panel mentioned above. According to embodiments of the present disclosure, refer to FIG. 29, the manufacturing method for the display panel mentioned above can include the following steps.

S110, a plurality of original display sub-panels are provided.

According to some embodiments of the present disclosure, in the step, the plurality of original display sub-panels are provided, and a structure of each of the original display sub-panels can refer to FIG. 11 and FIG. 12.

S120, a first frame and a second frame of each of the plurality of original display sub-panels are bent to a side away from a display surface of the original display sub-panel to obtain a display sub-panel.

According to some embodiments of the present disclosure, the display sub-panel 100 can be obtained by bending the first frame 110 and the second frame 120 of the original display sub-panel to the side away from the display surface of the original display sub-panel. According to some other embodiments of the present disclosure, refer to FIG. 11 and FIG. 12, the manufacturing method for the display panel can further include the step that a first bent part 130 is bent to the side away from the display surface. It should be noted that the display surface is a light emergent surface of the original display sub-panel or a light emergent surface of the display panel.

According to some other embodiments of the present disclosure, refer to FIG. 12, the manufacturing method for the display panel can further include the step that a third frame 160 is bent to the side away from the display surface.

S130, the first frame of the display sub-panel is arranged to be in contact with the second frame of another display sub-panel, and the plurality of display sub-panels are spliced to form the display panel.

In the step, the first frame 110 of each display sub-panel 100 can be arranged to be in contact with the second frame 120 of another display sub-panel 100, and the plurality of display sub-panels 100 are spliced to form a surrounding display structure, as shown in FIG. 2, FIG. 8, and FIG. 9; or the first frame 110 of a part of the display sub-panels 100 can be arranged to be in contact with the second frame 120 of another display sub-panel 100, and the plurality of display sub-panels 100 are spliced to form a display structure shown in FIG. 5 to FIG. 7.

Methods for manufacturing display panels with different shapes will be described in conjunction with specific structures in the accompanying drawings.

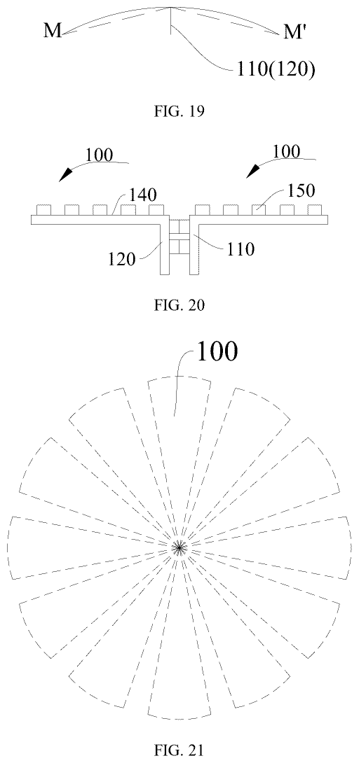

According to some embodiments of the present disclosure, refer to FIG. 11, the original display sub-panel can be fan-shaped (herein, it means that the original display sub-panel is approximately fan-shaped), a side, facing away from the display surface, of the original display sub-panel is fitted to a mold, the first frame 110 and the second frame 120 of the original display sub-panel 100 are bent to a side away from the display surface of the original display sub-panel to obtain the display sub-panel 100 (as shown in FIG. 10), wherein the mold can be of a sphere or a part of the sphere; the first frame 110 of one of the display sub-panels 100 is arranged to be in contact with the second frame 120 of another display sub-panel 100, specifically, as shown in FIG. 18 to FIG. 20, FIG. 18 shows a schematic diagram obtained before two display sub-panels are stretched, FIG. 19 is a schematic diagram showing that planes of the two display sub-panels in FIG. 18 are stretched into arc surfaces, cross sections of the two display sub-panels along MM' are shown in FIG. 19 in which the dashed line shows a schematic diagram obtained before the two display sub-panels are stretched and the full line shows a schematic diagram showing that the two display sub-panels are stretched along the mold to form arcs, the display sub-panels form arc surface structures by means of the mold, the operation is repeated, and the plurality of display sub-panels 100 are spliced to form a spherical display panel or a part of the spherical display panel, as shown in FIG. 2 to FIG. 4. A schematic structural diagram obtained after the two adjacent display sub-panels are spliced can refer to FIG. 20, the first frame 110 and the second frame 120 of the display sub-panel can be bent relative to a first display surface 140 for ninety degrees (vertically bent), and the first frame of one of the display sub-panels is arranged to be in contact with the second frame of another display sub-panel, in this way, the frames (splicing seams) cannot be seen visually, and thus, splicing without frames (splicing seams) is achieved.

It should be noted that the mold can be removed or retained after the splicing of the display panel is completed, and the retained mold can also play a good supporting role, of course, the retained mold also needs to be provided with a groove body structure for placing the first frame and the second frame.

According to some embodiments of the present disclosure, refer to FIG. 18 to FIG. 21, the plurality of display sub-panels can be firstly spliced into a hemisphere in FIG. 21, and two hemispheres are spliced to form a spherical display panel shown in FIG. 2. It should be noted that graphs decomposed from the hemisphere in FIG. 21 includes a plurality of fan-shaped arc surfaces similar to petals.

According to some embodiments of the present disclosure, the step that the plurality of display sub-panels 100 are spliced to form the display panel 1000 can further include: a third frame 160 of the original display sub-panel is bent to a side away from the display surface of the original display sub-panel. According to one embodiment of the present disclosure, as shown in FIG. 7, four display sub-panels can be sequentially arranged to be in contact, the second frame of the first display sub-panel can be in contact with the first frame of the second display sub-panel, the second frame of the second display sub-panel can be in contact with the first frame of the third display sub-panel, the second frame of the third display sub-panel can be in contact with the first frame of the fourth display sub-panel, and the third frame and/or the first bent part are only bent to a side away from the first display surface. According to another embodiment of the present disclosure, refer to FIG. 9, the four display sub-panels are sequentially arranged to be in contact or around, and the first frame (or the second frame) of each of the four display sub-panels is arranged to be in contact with the second frame (or the first frame) of another display sub-panel.

According to some embodiments of the present disclosure, the step that the plurality of display sub-panels 100 are spliced to form the display panel 1000 can further include: the third frame 160 of the display sub-panel 100 is arranged to be in contact with the third frame 160 or the first bent part 130 of another display sub-panel 100, as shown in FIG. 5, FIG. 6, and FIG. 8.

According to some embodiments of the present disclosure, the maximum size of the display sub-panel can be any value of three inches to twenty inches, for example, the maximum size of the display sub-panel can be three inches, five inches, eight inches, ten inches, fourteen inches, twenty inches, etc., and the maximum size refers to the maximum length of a connecting line between any two end points in the display sub-panel.

According to some embodiments of the present disclosure, refer to FIG. 22 to FIG. 24, manufacturing the original display sub-panel can include the following steps.

S111, an original substrate is provided.

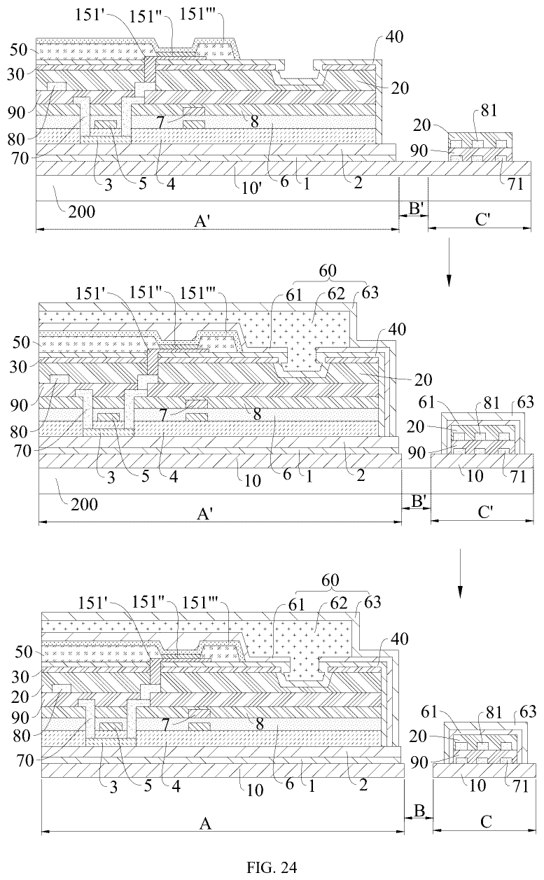

According to some embodiments of the present disclosure, refer to FIG. 22, the original substrate 10′ can include a first preset area A′, a second preset area B′ and a third preset area C′ respectively corresponding to the pixel island area A, the hollow area B and the connecting bridge area C in FIG. 24.

In the step, the original substrate 10′ can be placed on a surface of a base plate 200. According to some embodiments of the present disclosure, the base plate 200 can be a glass base plate, and can provide a flat surface and play a role in supporting other film layers.

S112, an original first planarization layer is formed on one side of the original substrate, and the original first planarization layer in the second preset area is removed.

According to some embodiments of the present disclosure, an original first planarization layer 20′ is formed on one side of the original substrate 10′, and the original first planarization layer 20′ in the second preset area B′ is removed. A material for forming the original first planarization layer 20′ can include polyimide.

According to some embodiments of the present disclosure, before the original first planarization layer 20′ is formed, refer to FIG. 22, the manufacturing method for the original display sub-panel can further include the step that a barrier layer 1, a buffer layer 2 and an active layer 3 are formed. According to embodiments of the present disclosure, the buffer layer can be formed by depositing one or two of silicon nitride and silicon oxide. After the buffer layer is formed, an amorphous silicon layer is deposited on a surface, away from the original substrate, of the buffer layer, after high-temperature dehydrogenation, amorphous silicon is converted into polycrystalline silicon by Excimer Laser Annealing (ELA), and a pattern of a channel layer is formed by exposure etching, wherein the channel layer can include partial ion doping, and thus, the active layer 3 is obtained.

According to some embodiments of the present disclosure, refer to FIG. 22, the manufacturing method for the original display sub-panel further includes the step that a first gate insulation layer 4, a first gate layer 5, a second gate insulation layer 6, a second gate layer 7, and an interlayer dielectric layer 8. Specifically, an original first gate insulation layer is formed, wherein the original first gate insulation layer covers a surface, away from the original substrate, of the active layer and a partial surface, away from the original substrate, of the buffer layer; a first gate metal is deposited and patterned to form the first gate layer 5, wherein the first gate layer 5 can include a first gate and a trace structure arranged on the same layer as the first gate; a second gate insulation material is deposited to form an original second gate insulation layer, wherein the original second gate insulation layer covers at least partial surface, away from the original substrate 10′, of the first gate layer 5 and a partial surface, away from the original substrate 10′, of the original first gate insulation layer; a second gate metal is deposited on a surface, away from the original substrate 10′, of the original second gate insulation layer and is patterned to form the second gate layer 7, wherein the second gate layer 7 can include a second gate and a trace structure arranged on the same layer as the second gate; an interlayer dielectric layer material is deposited to form an original interlayer dielectric layer, and exposure etching is performed to form a via hole, wherein the via hole passes through the original interlayer dielectric layer and the original second gate insulation layer and extends to a partial surface, away from the original substrate 10′, of the active layer 3, and in the step, all the barrier layer 1, the buffer layer 2, the original first gate insulation layer, the original second gate insulation layer, etc. in the third preset area C′ need to be etched to expose the original substrate 10′ in the third preset area C′.

According to some embodiments of the present disclosure, refer to FIG. 22, manufacturing the original display sub-panel can further include the steps that a first source-drain electrode layer 70 is formed, a second planarization layer 90 is formed, and a second source-drain electrode layer 80 is formed. According to embodiments of the present disclosure, a source-drain electrode metal is deposited and patterned to form the first source-drain electrode layer 70 and a first trace 71. The second planarization layer is formed, and etching is performed to form a via hole, wherein the via hole passes through the first source-drain electrode layer 70, and in the first preset area A′, the second planarization layer 90 covers a surface, away from the original substrate 10′, of the first source-drain electrode layer 70 and a partial surface, away from the original substrate 10′, of the interlayer dielectric layer 8; and in the third preset area C′, the second planarization layer 90 covers a surface of the first trace 71 and a partial surface of the original substrate 10′. A source-drain electrode metal is deposited and patterned to form the second source-drain electrode layer 80 and a second trace 81, wherein in the first preset area A′, the second source-drain electrode layer 80 can include a second source-drain electrode and a trace structure arranged on the same layer as the second source-drain electrode; and in the third preset area C′, the second trace 81 covers a partial surface, away from the original substrate 10′, of the second planarization layer 90.

It should be noted that when the original first planarization layer 20′ is formed, in the third preset area C′, the original first planarization layer 20′ covers a surface, away from the original substrate 10′, of the second trace 81 and the partial surface, away from the original substrate 10′, of the second planarization layer 90. In addition, refer to FIG. 22, after the original first planarization layer 20′ is formed, the method further includes the step that a via hole connected to an anode 151′ is formed: exposure etching is performed on the original first planarization layer 20′, so that a partial surface of the second source-drain electrode layer 80 is exposed, and the subsequently formed anode 151′ can be connected to the second source-drain electrode layer 80 via the via hole.

S113, an original first passivation layer is formed on a side, away from the original substrate, of the original first planarization layer, the original first passivation layer in the second preset area and the third preset area is removed, the original first passivation layer and the original first planarization layer in the first preset area are etched by adopting a gas to obtain a first planarization layer, and an opening is formed in the original first passivation layer, wherein the first planarization layer is provided with a groove, a cross section of the groove in a first direction is of an inverted trapezoid, and the first direction is a direction that the original substrate points to the first planarization layer; and an orthographic projection of the first opening on the original substrate falls within a range of an orthographic projection of an edge, away from the original substrate, of the groove on the original substrate.

In the step, an original first passivation layer 30′ is formed on a side, away from the original substrate 10′, of the original first planarization layer 20′, the original first passivation layer 30′ in the second preset area B′ and the third preset area C′ is removed by patterning, the original first passivation layer 30′ and the original first planarization layer 20′ in the first preset area A′ are etched by adopting a gas to obtain a first planarization layer 20, and an opening 31 is formed in the original first passivation layer 30′ (refer to FIG. 16), wherein refer to FIG. 22 and FIG. 16, the first planarization layer 20 is provided with a groove 21, a cross section of the groove 21 in a first direction is of an inverted trapezoid, and the first direction (i.e., a Y direction shown in FIG. 22) is a direction that the original substrate 10′ points to the first planarization layer 20; and an orthographic projection of the first opening 31 on the original substrate 10′ falls within a range of an orthographic projection of an edge, away from the original substrate 10′, of the groove 21 on the original substrate 10′. In the step, the original first passivation layer 30′ is used as a mask to form an undercut structure on the first planarization layer 20, which can effectively prevent a cathode material from entering the downside of a “cap peak” of the undercut structure when the cathode material is deposited subsequently, thereby improving the stability of the display panel and being beneficial to prolonging the service life of the display panel.

According to some embodiments of the present disclosure, a material for forming the original first passivation layer 30′ can include one or more of silicon nitride, silicon oxide, and silicon oxynitride.

S114, an original second passivation layer is formed on a side, away from the original substrate, of the original first passivation layer.

According to embodiments of the present disclosure, an original second passivation layer 40′ is formed on a side, away from the original substrate 10′, of the original first passivation layer 30′. Refer to FIG. 22, the original second passivation layer 40′ covers a surface, away from the original substrate 10′, of the original first passivation layer 30′, the bottom of the groove 21 and at least part side wall of the groove 21, the original second passivation layer 40′ is provided with a second opening 41, the area of an orthographic projection of a part, located on the bottom of the groove 21, of the original second passivation layer 40′ on the original substrate 10′ is greater than the area of an orthographic projection of the second opening 41 on the original substrate 10′, and the orthographic projection of the part, located on the bottom of the groove 21, of the original second passivation layer 40′ on the original substrate 10′ covers the orthographic projection of the second opening 41 on the original substrate 10′.

S115, exposure etching is performed on the original second passivation layer and the original first passivation layer to form a first via hole, thereby obtaining a second passivation layer and a first passivation layer.

Refer to FIG. 22, in the step, a passivation layer material is deposited to form the original second passivation layer 40′, exposure etching is performed on the original second passivation layer 40′ and the original first passivation layer 30′ to form a first via hole 9 (refer to FIG. 6), the second source-drain electrode layer 80 is exposed to form a second passivation layer 40, and the second passivation layer 40 covers an undercut structure.

According to some embodiments of the present disclosure, a material of the second passivation layer 40 can include one or more of silicon nitride, silicon oxide, and silicon oxynitride.

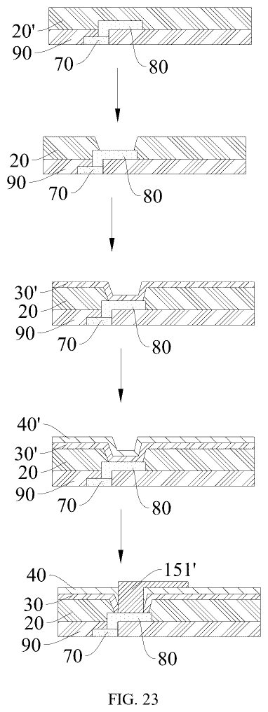

In some embodiments of the present disclosure, refer to FIG. 23, after the original first planarization layer 20′ is formed, a groove-shaped via hole shown in FIG. 23 can be formed by exposure to expose a partial surface of the second source-drain electrode layer 80; then, the original first passivation layer 30′ is formed, and the original first passivation layer 30′ covers a partial surface of the first planarization layer 20 and a partial surface of the second source-drain electrode layer 80; the original second passivation layer 40′ is formed, above the second source-drain electrode layer 80, each of the original first passivation layer 30′ and the original second passivation layer 40′ can also have a groove-shaped structure, exposure etching is performed on the original second passivation layer 40′ and the original first passivation layer 30′ to expose a partial surface of the second source-drain electrode layer 80, and then, the anode 151′ is formed. It should be noted that FIG. 23 only shows parts of structures such as a first planarization layer 20, a first passivation layer 30, and a second passivation layer 40, but shows no undercut structure. In addition, a part of the first planarization layer 20 can also be etched according to an actual demand in the process that the original second passivation layer 40′ is etched to form the first via hole.

S116, a plurality of light emitting units are formed in the first preset area.

The pixel can include a plurality of sub-pixels. According to some embodiments of the present disclosure, each pixel can include a blue sub-pixel, a red sub-pixel, and a green sub-pixel. The light emitting unit serves as a part of the sub-pixels, and can include an anode 151′, a light emitting layer 151″, and a cathode 151′″.

The step that a plurality of light emitting units are formed in the first preset area A′ can include the steps that a blue light emitting unit is formed, a red light emitting unit is formed, and a green light emitting unit is formed.

According to some embodiments of the present disclosure, an anode metal is deposited and patterned to form the anode 151′, and a material of the anode 151′ can include at least one of Indium Tin Oxide (ITO) and Argentum (Ag). According to some embodiments of the present disclosure, the anode 151′ can include a first indium tin oxide layer, an argentum layer and a second indium tin oxide layer that are sequentially stacked.

According to some embodiments of the present disclosure, a pixel defining layer 50 can be formed by coating and exposure, the pixel defining layer 50 covers a partial surface, away from the original substrate 10′, of the second passivation layer 40 and a partial surface, away from the original substrate 10′, of the anode 151′, moreover, refer to FIG. 22, a plurality of third openings 51 are defined by the pixel defining layer 50, then, the light emitting layer 151″ can be formed in the third openings 51 by evaporating an organic light emitting material, and then, a cathode metal is evaporated on a side, away from the original substrate 10′, of the light emitting layer 151″ to form the cathode 151′″. Of course, the step that the light emitting units are formed can also include the step that a hole injection layer, a hole transport layer, an electron transport layer and an electron injection layer are formed.

S117, the original substrate in the second preset area is removed to form the hollow area.

After the light emitting units are formed, the hollow area B can be formed by etching the original substrate 10′ in the second preset area B′, the base plate 200 is removed, and thus, the original display sub-panel can be obtained.

According to some other embodiments of the present disclosure, refer to FIG. 24, manufacturing the original display sub-panel can further include the step that a packaging layer 60 is formed: a first inorganic packaging film layer 61 is formed, wherein the first inorganic packaging film layer 61 can be formed by chemical vapor deposition; in the first preset area A′, the first inorganic packaging film layer 61 covers at least partial surface, away from the original substrate 10′, of the cathode 151′″ and at least partial surface, away from the original substrate 10′, of the second passivation layer 40; in the third preset area C′, the first inorganic packaging film layer 61 covers a partial surface of the original substrate 10′ and a surface, away from the original substrate 10′, of the first planarization layer 20; and in the second preset area B′, the inorganic packaging film layer 61 can cover at least partial surface (unshown in FIG. 24) of the original substrate 10′. An organic packaging film layer 62 is formed, wherein the organic packaging film layer 62 is of a patterned structure, the second opening 41 is filled with the organic packaging film layer 62 covering at least partial surface, away from the original substrate, of the first inorganic packaging film layer 61, and no organic packaging film layer is arranged in the third preset area C′. A second inorganic packaging film layer 63 is formed, wherein the second inorganic packaging film layer 63 can also be formed by chemical vapor deposition; in the first preset area A′, the second inorganic packaging film layer 63 covers a partial surface of the first inorganic packaging film layer 61 and a surface, away from the original substrate 10′, of the organic packaging film layer 62; in the third preset area C′, the second inorganic packaging film layer 63 covers a surface of the first inorganic packaging film layer 61 and a partial surface of the original substrate 10′; and in the second preset area B′, the second inorganic packaging film layer 63 can cover at least partial surface (unshown in FIG. 24), away from the original substrate 10′, of the first inorganic packaging film layer 61.

According to some embodiments of the present disclosure, after the packaging layer 60 is formed, the first inorganic packaging film layer 61 and the second inorganic packaging film layer 62 in the second preset area B′ can be removed by etching to expose the original substrate 10′, then, the original substrate 10′ in the second preset area B′ is removed by exposure etching to form a via hole in the second preset area B′, thereby obtaining the hollow area B. According to some embodiments of the present disclosure, a protective film can be stuck to a side, away from the substrate 10, of the packaging layer 60, the base plate 200 is taken down by means of laser, the protective film is removed, and thus, the original display sub-panel can be obtained.

In a further aspect of the present disclosure, the present disclosure provides a manufacturing method for a display panel. According to some embodiments of the present disclosure, refer to FIG. 30, the manufacturing method for the display panel can include the following steps.

S210, a pixel spacing is calculated according to a width of a fourth frame, a width of a fifth frame and a fit tolerance of a display sub-panel.

In the step, a pixel spacing D can be calculated according to a width Wi of a fourth frame, a width W₂ of a fifth frame and a fit tolerance W₃ of a display sub-panel 100, wherein D=W₁+W₂+W₃.

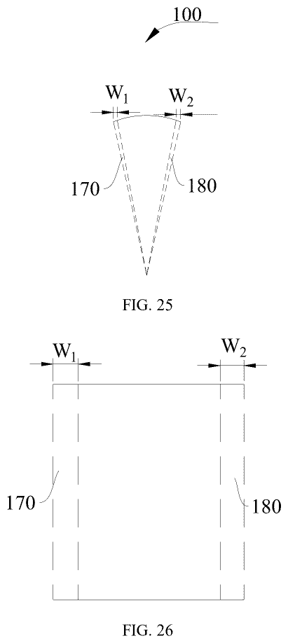

Refer to FIG. 25, the display sub-panel 100 can be fan-shaped, the width W₁ of the fourth frame 170 and the width W₂ of the fifth frame 180 can be an average width; and refer to FIG. 26, the display sub-panel 100 can be rectangular, and the fourth frame 170 and the fifth frame 180 can be rectangular frames. No pixel structures are arranged in the fourth frame and the fifth frame, and the fourth frame and the fifth frame have no display function.

S220, a plurality of display sub-panels are manufactured, wherein a spacing between two adjacent pixels in each of the plurality of display sub-panels is the pixel spacing, and the display sub-panel is provided with the fourth frame and the fifth frame.

In the step, a plurality of display sub-panels 100 can be manufactured, wherein a spacing between two adjacent pixels in each display sub-panel 100 is the pixel spacing D, and each display sub-panel 100 is provided with the fourth frame 170 and the fifth frame 180.

S230, the plurality of display sub-panels are spliced to form the display panel, wherein the fourth frame of at least one of the plurality of display sub-panels is arranged to be in contact with the fifth frame of a display sub-panel adjacent to the display sub-panel.

In the step, the plurality of display sub-panels 100 are to form the display panel, wherein the fourth frame 170 of at least one of the plurality of display sub-panels 100 is arranged to be in contact with the fifth frame 180 of a display sub-panel 100 adjacent to the display sub-panel 100.

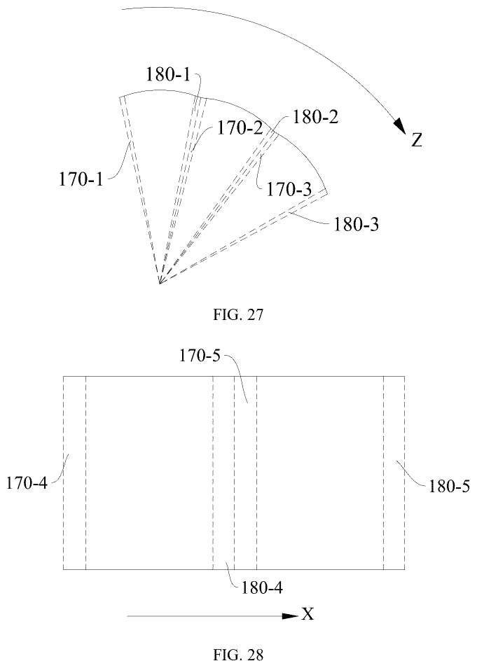

According to some embodiments of the present disclosure, refer to FIG. 27, a plurality of fan-shaped display sub-panels can be spliced to form a irregular display panel, and in a second direction (i.e., a Z direction shown in FIG. 27), a fourth frame 170-1 of a first display sub-panel and a fifth frame 180-3 of a third display sub-panel can be not in contact with other display sub-panels, a fourth frame 170-2 of a second display sub-panel is arranged to be in contact with a fifth frame 180-1 of the first display sub-panel, a fifth frame 180-2 of the second display sub-panel is arranged to be in contact with a fourth frame 170-3 of the third display sub-panel, and the fourth frame 170 and the fifth frame 180 of each display sub-panel do not need to be bent to a side away from the display surface.

According to some other embodiments of the present disclosure, refer to FIG. 28, a plurality of rectangular display sub-panels can be spliced to form a rectangular display panel, and in a third direction (i.e., an X direction shown in FIG. 28), a fourth frame 170-4 of a fourth display sub-panel and a fifth frame 180-5 of a fifth display sub-panel do not need to be bent, and a fifth frame 180-4 of the fourth display sub-panel is arranged to be in contact with a fourth frame 170-5 of the fifth display sub-panel.

It should be noted that the display sub-panel used in the method can also be provided with a first bent part which is bent to the side away from the display surface. Of course, in some embodiments, the display sub-panel can also be provided with a sixth frame in contact with both of the fourth frame and the fifth frame, and during splicing, the sixth frame of one of the display sub-panels can be arranged to be in contact with an edge, close to the display surface, of the sixth frame or the first bent part of another display sub-panel.

The display panel manufactured by using the above-mentioned method has no obvious splicing seams, too, and has a better display effect, and a watcher achieves a better experience effect.

In a yet further aspect of the present disclosure, the present disclosure provides a display apparatus. According to some embodiments of the present disclosure, the display apparatus can include the display panel mentioned above or the display panel manufactured by using the method mentioned above. Therefore, the display apparatus has a good display effect, and thus, a watcher achieves a better experience effect.

According to embodiments of the present disclosure, a specific type of the above-mentioned display apparatus is not specially required, and can be flexibly selected by the skilled in the art according to actual demands. It can be understood by the skilled in the art that the display apparatus can also be provided with essential structures and components such as a touch panel and an audio module of a conventional display apparatus in addition to the display panel mentioned above.

Terms “first”, “second”, “third”, “fourth”, “fifth”, and “sixth” in the present disclosure are for descriptive purposes only, and cannot be understood as indicating or implying the relative importance or implicitly indicating a quantity of indicated technical features. Therefore, features defined as “first”, “second”, “third ”, “fourth”, “fifth”, and “sixth” can explicitly or implicitly include one or more of the features. In the description of the present disclosure, “a plurality of” means two or more unless it is specifically defined otherwise.

In the description of the present description, the description with reference to terms such as “one embodiment”, “another embodiment”, “some embodiments”, “some specific embodiments” or “some other specific embodiments” is intended to indicate that specific features, structures, materials or characteristics described in conjunction with the embodiment or example are included in at least one embodiment or example of the present disclosure. In the present description, the schematic statement for the above-mentioned terms does not necessarily refer to the same embodiment or example. Moreover, the described specific features, structures, materials or characteristics can be combined in an appropriate way in any one or more embodiments or examples. In addition, different embodiments or examples and features of the different embodiments or examples described in the present description can be integrated and combined without conflicts by the skilled in the art.

Although the embodiments of the present disclosure have been shown and described as above, it can be understood that the above-mentioned embodiments are exemplary, but cannot be understood as limitations on the present disclosure, and persons skilled in the art can perform variations, alterations, replacements and modifications on the above-mentioned embodiments within the scope of the present disclosure.

1. A display panel, wherein the display panel is formed by splicing a plurality of display sub-panels; and
each of the plurality of display sub-panels is provided with a first display surface, the display sub-panel is provided with a first frame and a second frame, the first frame and the second frame are bent to a side away from the first display surface, and the first frame of at least one of the plurality of display sub-panels is arranged to be in contact with the second frame of a display sub-panel adjacent to the display sub-panel.

2. The display panel according to claim 1, wherein the display sub-panels are provided with a plurality of hollow areas.

3. The display panel according to claim 2, wherein the display sub-panels comprise a plurality of pixel island areas and a plurality of connecting bridge areas, the hollow areas are located between the pixel island areas and the connecting bridge areas, two of the adjacent pixel island areas are connected by the connecting bridge areas, and the connecting bridge areas comprise traces.

4. The display panel according to claim 3, wherein the display sub-panel comprises a substrate, a first planarization layer, and a first passivation layer, the substrate and the first planarization layer are located in the pixel island area and the connecting bridge area, and the first passivation layer is located in the pixel island area;
the first planarization layer is located on one side of the substrate and is provided with a groove, a cross section of the groove in a first direction is of an inverted trapezoid, and the first direction is a direction that the substrate points to the first planarization layer; and
the first passivation layer covers a partial surface, away from the substrate, of the first planarization layer, the first passivation layer is provided with a first opening, and an orthographic projection of the first opening on the substrate falls within a range of an orthographic projection of an edge, away from the substrate, of the groove on the substrate.

5. The display panel according to claim 4, wherein the display sub-panel further comprises a second passivation layer, the second passivation layer is located in the pixel island area, the second passivation layer covers a surface, away from the substrate, of the first passivation layer, a bottom of the groove and at least a part of a side wall of the groove, the second passivation layer is provided with a second opening, an area of an orthographic projection of a part, located on the bottom of the groove, of the second passivation layer on the substrate is greater than an area of an orthographic projection of the second opening on the substrate, and the orthographic projection of the part, located on the bottom of the groove, of the second passivation layer on the substrate covers the orthographic projection of the second opening on the substrate.

6. The display panel according to claim 5, wherein the display sub-panel further comprises a pixel defining layer, an anode, a light emitting layer, and a cathode, the pixel defining layer, the anode and the cathode are located in the pixel island area, the pixel island area comprises at least one pixel, the anode covers a partial surface, away from the substrate, of the second passivation layer, a plurality of third openings are defined by the pixel defining layer, the pixel defining layer covers a partial surface, away from the substrate, of the anode, at least partial areas of the third openings are filled with the light emitting layer, the cathode is located on a side, away from the substrate, of the light emitting layer, the cathode covers a partial surface, away from the substrate, of the pixel defining layer, and an orthographic projection of the cathode on the substrate does not overlap with an orthographic projection of the groove on the substrate.

7. The display panel according to claim 1, wherein the display sub-panel is provided with a first bent part, the first bent part comprises a flexible circuit board and an integrated circuit, and the first bent part is bent to a side away from the first display surface.

8. The display panel according to claim 7, wherein the first bent part comprises a stretchable transition area located between the first display surface and the flexible circuit board and provided with a first side and a second side, the first side partially overlaps with an edge of the first display surface, and the second side at least partially overlaps with an edge of the flexible circuit board.

9. The display panel according to claim 8, wherein a distance between the first side and the second side is greater than or equal to one millimeter.

10. The display panel according to claim 1, wherein the display sub-panel is fan-shaped, and the display panel is of a sphere or a part of the sphere.

11. The display panel according to claim 10, wherein
the display panel is of the part of the sphere, and a quantity of the display sub-panels in the display panel is any value of two to ten; or
the display panel is of the sphere, and a quantity of the display sub-panels in the display panel is any value of eight to twenty.

12. The display panel according to claim 8, wherein the at least one display sub-panel is further provided with a third frame, the third frame is located on one end of the display sub-panel, and the third frame is bent to a side away from the first display surface.

13. The display panel according to claim 12, wherein
a display surface of the display panel is a rectangular plane or an irregular plane, and the third frame of the at least one display sub-panel is arranged to be in contact with the third frame or the first bent part of another display sub-panel; or
the display panel is provided with six display surfaces, and the six display surfaces of the display panel form six surfaces of a cuboid; or
the display panel is provided with four display surfaces, and the four display surfaces of the display panel are sequentially connected to form four sides of a cuboid.

14. A manufacturing method for the display panel according to claim 1, comprising:
providing a plurality of original display sub-panels;
bending a first frame and a second frame of each of the plurality of original display sub-panels to a side away from a display surface of the original display sub-panel to obtain a display sub-panel; and
disposing the first frame of the display sub-panel to be in contact with the second frame of another display sub-panel, and splicing the plurality of display sub-panels to form the display panel.

15. The method according to claim 14, wherein
the original display sub-panel is fan-shaped, a side, facing away from the display surface, of the original display sub-panel is fitted to a mold, the first frame and the second frame of the original display sub-panel are bent to a side away from the display surface of the original display sub-panel to obtain the display sub-panel, wherein the mold is of a sphere or a part of the sphere;
the first frame of one of the display sub-panels is arranged to be in contact with the second frame of another display sub-panel, the operation is repeated, and the plurality of display sub-panels are spliced to form a spherical display panel or a part of the spherical display panel; or
the splicing the plurality of display sub-panels to form the display panel further comprises: bending a third frame of the original display sub-panel to a side away from the display surface of the original display sub-panel; or
the splicing the plurality of display sub-panels to form the display panel further comprises: disposing the third frame of the display sub-panel to be in contact with the third frame or the first bent part of another display sub-panel.

16. The method according to claim 14, wherein manufacturing the original display sub-panel comprises:
providing an original substrate, wherein the original substrate comprises a first preset area, a second preset area, and a third preset area;
forming an original first planarization layer on one side of the original substrate, and removing the original first planarization layer in the second preset area; and
forming an original first passivation layer on a side, away from the original substrate, of the original first planarization layer, removing the original first passivation layer in the second preset area and the third preset area, etching the original first passivation layer and the original first planarization layer in the first preset area by adopting a gas to obtain a first planarization layer, and forming an opening in the original first passivation layer, wherein the first planarization layer is provided with a groove, a cross section of the groove in a first direction is of an inverted trapezoid, and the first direction is a direction that the original substrate points to the first planarization layer; and an orthographic projection of the first opening on the original substrate falls within a range of an orthographic projection of an edge, away from the original substrate, of the groove on the original substrate.

17. The method according to claim 16, wherein manufacturing the original display sub-panel further comprises:
forming an original second passivation layer on a side, away from the original substrate, of the original first passivation layer, wherein the original second passivation layer covers a surface, away from the original substrate, of the original first passivation layer, the bottom of the groove and at least part side wall of the groove, the original second passivation layer is provided with a second opening, the area of an orthographic projection of a part, located on the bottom of the groove, of the original second passivation layer on the original substrate is greater than the area of an orthographic projection of the second opening on the original substrate, and the orthographic projection of the part, located on the bottom of the groove, of the original second passivation layer on the original substrate covers the orthographic projection of the second opening on the original substrate;
performing exposure etching on the original second passivation layer and the original first passivation layer to form a first via hole, thereby obtaining a second passivation layer and a first passivation layer;
forming a plurality of light emitting units in the first preset area; and
removing the original substrate in the second preset area to form the hollow area.

18. A manufacturing method for a display panel, comprising:
calculating a pixel spacing according to a width of a fourth frame, a width of a fifth frame and a fit tolerance of a display sub-panel;
manufacturing a plurality of display sub-panels, wherein a spacing between two adjacent pixels in each display sub-panel is the pixel spacing, and the display sub-panel is provided with the fourth frame and the fifth frame; and
splicing the plurality of display sub-panels to form the display panel, wherein the fourth frame of at least one of the plurality of display sub-panels is arranged to be in contact with the fifth frame of a display sub-panel adjacent to the display sub-panel.

19. A display apparatus, comprising the display panel according to claim 1.
